(19) United States
(12) Patent Application Publication
(10) Pub. No.: US 2014/0125422 A1
(43) Pub. Date: May 8, 2014

(54) SELF-OSCILLATION CIRCUIT

(71) Applicant: NIHON DEMPA KOGYO CO., LTD., Tokyo (JP)

(72) Inventors: MITSUAKI KOYAMA, SAITAMA (JP); TAKERU MUTOH, SAITAMA (JP); MANABU ISHIKAWA, SAITAMA (JP)

(73) Assignee: NIHON DEMPA KOGYO CO., LTD., Tokyo (JP)

(21) Appl. No.: 14/072,807

(22) Filed: Nov. 6, 2013

(30) Foreign Application Priority Data
Nov. 7, 2012 (JP) 2012-245518

(51) Int. Cl. H03B 5/36

(52) U.S. Cl. CPC H03B 5/362
USPC 331/116 R

(57) ABSTRACT

A self-oscillation circuit includes an oscillating unit, an amplifying unit, and a resonator. The oscillating unit is configured to self-oscillate. The amplifying unit is configured to amplify a frequency signal oscillated at the oscillating unit and to feed back the amplified frequency signal to the oscillating unit. The resonator is disposed in an oscillation loop that includes the oscillating unit and the amplifying unit. The resonator has a resonant frequency near an oscillation frequency of the oscillating unit and has a higher Q-value than a Q-value of the oscillating unit.

### CROSS REFERENCE TO RELATED APPLICATIONS

This application claims the priority benefit of Japan application serial no. 2012-245518, filed on Nov. 7, 2012. The entirety of the above-mentioned patent application is hereby incorporated by reference herein and made a part of this specification.

### TECHNICAL FIELD

This disclosure relates to a self-oscillation circuit with an oscillating unit that self-oscillates.

### DESCRIPTION OF THE RELATED ART

An oscillation circuit that includes a crystal resonator is utilized widely in the information communication field. Further reduction in size, reduction in electric power, and high frequency stability are required for this oscillation circuit. Typically, as the crystal resonator is reduced in size, the upper limit (drive withstand current) of drive current for stable operation is known to be decreased. On the other hand, considering stability in oscillation frequency against electronic noise and temperature change, it may be difficult to have a smaller drive current for oscillating the crystal resonator than the drive withstand current.

For example, in claim 1 and paragraph 0011 of Japanese Unexamined Patent Application Publication No. 2008-157751 (hereinafter referred to as Patent Literature 1), the following technique is disclosed. A sensing instrument senses a substance to be sensed in a liquid by adsorption of an adsorption layer formed on a surface of a piezoelectric resonator. In this sensing instrument, a drive current for oscillating the piezoelectric resonator is set to 0.3 mA or less. This suppresses self-heating of the piezoelectric resonator and precisely obtains frequency change due to the absorption of the substance to be sensed. However, Patent Literature 1 does not disclose any method for solving the above-described problem occurring when the drive current supplied to the piezoelectric resonator is decreased.

In paragraph 0003 to 0013 and FIG. 3 of Japanese Unexamined Patent Application Publication No. 2002-232234 (hereinafter referred to as Patent Literature 2), the following method is disclosed. In an oscillation loop of a Colpitts oscillation circuit, an overtone resonator constituted of a crystal resonator is disposed. This overtone resonator is used as a filter that allows passage of a predetermined overtone frequency so as to narrow the bandwidth of the oscillation frequency. Similarly, Patent Literature 2 does not disclose any technique for obtaining a stable oscillation frequency while decreasing the drive current.

A need thus exists for a self-oscillation circuit which is not susceptible to the drawback mentioned above.

### SUMMARY

A self-oscillation circuit according to this disclosure includes an oscillating unit, an amplifying unit, and a resonator. The oscillating unit is configured to self-oscillate. The amplifying unit is configured to amplify a frequency signal oscillated at the oscillating unit and to feed back the amplified frequency signal to the oscillating unit. The resonator is disposed in an oscillation loop that includes the oscillating unit and the amplifying unit. The resonator has a resonant frequency near an oscillation frequency of the oscillating unit and has a higher Q-value than a Q-value of the oscillating unit.

### BRIEF DESCRIPTION OF THE DRAWINGS

The foregoing and additional features and characteristics of this disclosure will become more apparent from the following detailed description considered with the reference to the accompanying drawings, wherein:

FIG. 1 illustrates a Colpitts-type self-oscillation circuit according to an embodiment disclosed here.

FIG. 2A and FIG. 2B illustrate a circuit component disposed at the self-oscillation circuit.

FIG. 3 illustrates a partially enlarged plan view of the circuit component.

FIG. 4A and FIG. 4B illustrate a crystal resonator constituting a resonator disposed at the self-oscillation circuit.

FIG. 5 illustrates a first example of a SAW crystal resonator constituting the resonator.

FIG. 6 illustrates a second example of the SAW crystal resonator constituting the resonator.

FIG. 7A and FIG. 7B illustrate an example of a MEMS crystal resonator constituting the resonator.

FIG. 8 illustrates a first modification of the self-oscillation circuit.

FIG. 9 illustrates a second modification of the self-oscillation circuit.

FIG. 10 illustrates a third modification of the self-oscillation circuit.

FIG. 11 illustrates a fourth modification of the self-oscillation circuit.

FIG. 12 illustrates a configuration example of a Pierce-type self-oscillation circuit.

FIG. 13 illustrates a configuration example of a Clapp-type self-oscillation circuit.

FIG. 14 illustrates a configuration example of a Butler-type self-oscillation circuit.

FIG. 15 illustrates an example of the self-oscillation circuit where an oscillation circuit part is constituted of an RC oscillation circuit.

FIG. 16 illustrates a temperature versus frequency characteristic of the self-oscillation circuit according to a working example.

FIG. 17 illustrates a temperature versus frequency characteristic of the self-oscillation circuit according to a comparative example.

### DETAILED DESCRIPTION

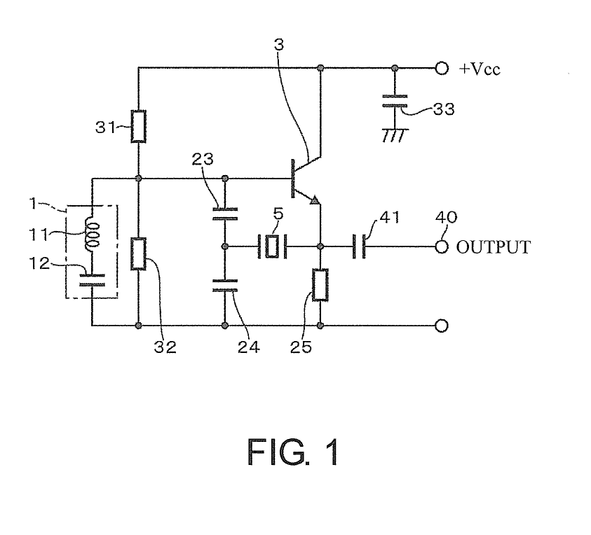

FIG. 1 is a circuit diagram illustrating an embodiment of a self-oscillation circuit of this disclosure. The circuit of FIG. 1 is constituted as a Colpitts-type oscillation circuit. An oscillating unit 1 is an LC oscillation circuit where an inductor 11 and a capacitor (condenser) 12 are connected together in series. One end side of the oscillating unit 1 connects to a base of a NPN-type transistor 3 as an amplifying unit. The transistor 3 amplifies a frequency signal, which is oscillated by the oscillating unit 1, and feeds back the amplified signal to the oscillating unit 1. At a base side of the transistor 3, a series circuit of voltage-dividing capacitors 23 and 24 are disposed in parallel to the oscillating unit 1. The middle point between these capacitors 23 and 24 connects to an emitter of the transistor 3.

A direct current power source unit Vcc applies a DC voltage of +Vcc to a series circuit of bleeder resistors 31 and 32. The voltage at the middle point of the bleeder resistors 31 and 32 is supplied to the base of the transistor 3. Reference numeral 33 denotes a capacitor and reference numeral 25 denotes a feedback resistor. On the other hand, the emitter side of the transistor 3 connects to an output terminal 40 through a capacitor 41 for extracting an output frequency signal.

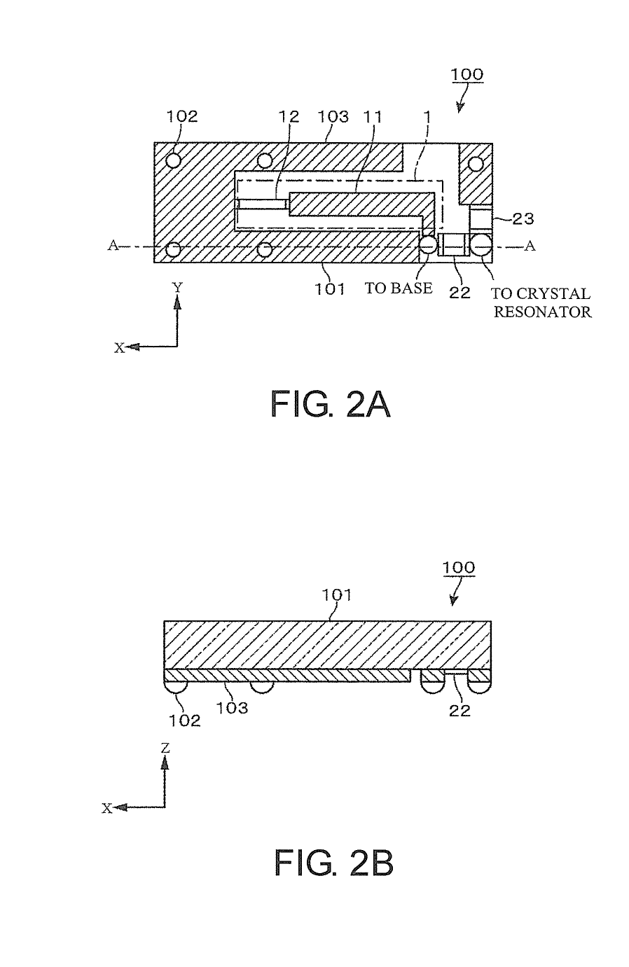

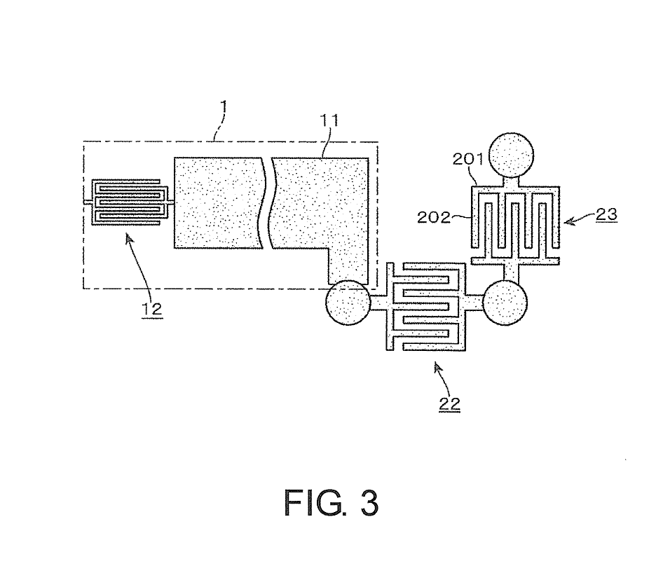

In the oscillation circuit with the above-described configuration in this example, the inductor 11, the capacitor 12, and the voltage-dividing capacitors 23 and 24 are constituted as a common circuit component 100 for reduction in size of the device. As illustrated in FIG. 2A, FIG. 2B, and FIG. 3, the circuit component 100 is formed by etching a metal film formed on a quartz substrate 101 that has, for example, a dimension of some several mm square, using a photolithography method or similar method.

The quartz substrate 101 is, for example, an AT-cut blank that has a relative permittivity ∈ of about 4.0 and a loss in electric energy (a dielectric loss tangent: tan δ) of about 0.00008. Therefore, a Q-value of this quartz substrate 101 is about 12500 (=1/0.00008).

Each of the capacitors 12, 22, and 23 described above is illustrated in a simplified form in FIG. 2A, but is actually constituted of a comb electrode as illustrated in the enlarged figure in FIG. 3. For example, the comb electrode includes a pair of common electrode portions 201 and interdigital transducer (IDT) electrode fingers 202. The pair of common electrode portions 201 are formed parallel to each other. The respective IDT electrode fingers 202 extend from these common electrode portions 201 so as to be interlaced with one another in a comb shape. The respective common electrode portions 201 connect to a contacting terminal 102 and the inductor 11, which will be described later.

On the other hand, the inductor 11 is constituted of a stripline that is a conductive line. Each of electrode films connected to the capacitors 12 and 23 is an earth electrode 103. Each of extruding parts disposed in contact with the earth electrode 103, the inductor 11, and the capacitors 22 and 23 is the contacting terminal 102. Here, FIG. 2B illustrates a longitudinal cross-sectional side view of the circuit component 100 taken along the line A-A in FIG. 2A.

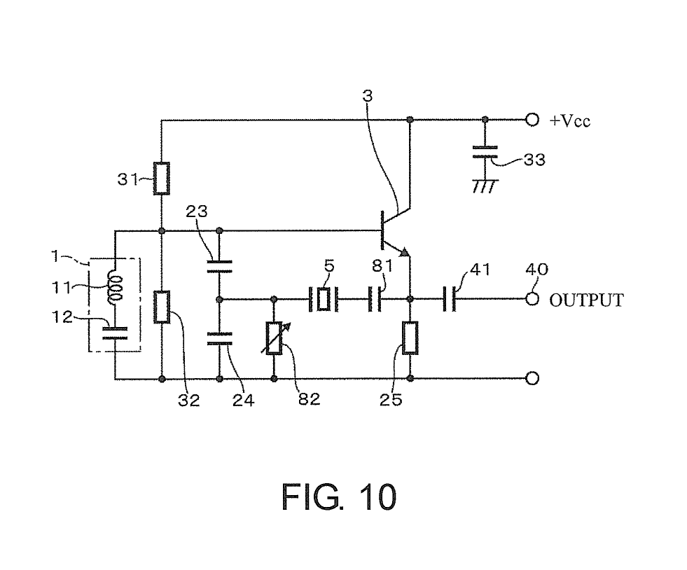

Accordingly, a circuit part that includes the oscillating unit 1 is formed on the quartz substrate 101 with an extremely small dielectric loss tangent (high Q-value). This keeps extremely low phase noise over a wide frequency band compared with, for example, the case where the circuit part is formed on a fluorine resin substrate (where the Q-value=1000), which is conventionally used (specifically, see FIG. 10 of Japanese Unexamined Patent Application Publication No. 2011-82710 and its related description). The oscillating unit 1 (the inductor 11 and the capacitor 12) and the capacitors 22 and 23 are formed in one chip using a photolithography method. This allows a configuration of the circuit component 100 with small size and high resistance to physical impact for example. Here, the above-described circuit component 100 has been described as one preferable example. Apparently, the self-oscillation circuit described in FIG. 1 may be constituted by arranging the inductor 11, the capacitor 12, and other elements of the circuit part on an ordinary fluorine resin substrate or similar substrate.

As described above, the self-oscillation circuit that includes the oscillating unit 1 constituted of the LC oscillation circuit can generate a frequency signal with a smaller drive current compared with, for example, a crystal oscillation circuit that includes a crystal resonator as an oscillating unit. Especially, an advantage with the LC oscillation circuit that oscillates with the small drive current is that rapid frequency variation and resistance variation (activity dips and the frequency dips) when a continuous temperature change is applied to the crystal resonator do not easily occur.

On the other hand, the self-oscillation circuit that includes the LC oscillation circuit as the oscillating unit 1 is typically inferior in frequency stability to the crystal oscillation circuit. Accordingly, the crystal oscillation circuit is utilized more widely than the LC oscillation circuit in reality. The self-oscillation circuit in this example has the following feature. As illustrated in FIG. 1, a resonator (a crystal resonator 5) is disposed between: the middle point of the capacitors 23 and 24, and the emitter of the transistor 3. This improves the overall frequency stability of the self-oscillation circuit.

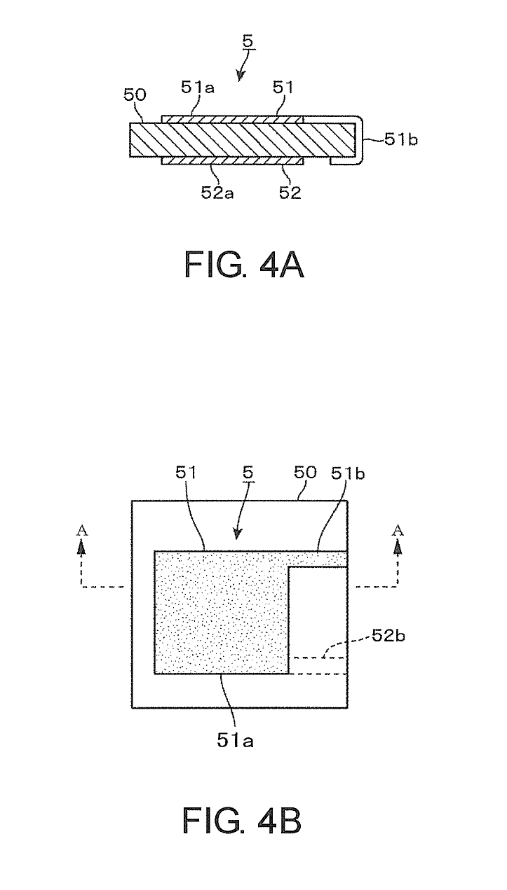

As illustrated in FIG. 4A and FIG. 4B, the crystal resonator 5 disposed at the self-oscillation circuit in this example includes paired electrodes 51 and 52 on respective front and back surfaces of AT-cut strip-shaped crystal element 50. Each of these electrodes 51 and 52 includes a rectangular excitation electrode 51a (52a) and an extraction electrode 51b (52b) extracted from this excitation electrode 51a (52a). The extraction electrode 51b on the front side of the crystal element 50 is extended to the back side such that the extraction electrodes 51b and 52b are arranged side by side at mutually different positions in plain view on the back side.

A description will be given of an operation in the case, where the crystal resonator 5 with the above-described configuration is disposed in the oscillation loop of this self-oscillation circuit. For example, the self-oscillation circuit generates a frequency signal with a frequency of 20 MHz to 30 MHz. In this case, the Q-value of the LC oscillation circuit is about 100 to 1000. On the other hand, the crystal resonator 5 can have a high Q-value on the order of 10⁴ to 10⁶. The inventors found that in the case where the crystal resonator 5 with this high Q-value is disposed in the oscillation loop that includes the oscillating unit 1 (the LC oscillation circuit) and the amplifying unit (the transistor 3), the overall frequency stability of the oscillation loop improved by effect of entrainment (synchronization) caused by the crystal resonator 5. In other words, disposing the crystal resonator 5 allows the self-oscillation circuit to operate as if the Q-value of the LC oscillation circuit in the oscillation loop is replaced by the Q-value of the crystal resonator 5.

Here, the self-oscillation circuit is oscillated by the LC oscillation circuit of the oscillating unit 1. The crystal resonator 5 disposed in the oscillation loop functions only as a filter that allows passage of a frequency signal at a predetermined frequency. This reduces the drive current for oscillating the oscillating unit 1 mA to 0.3 mA or less, preferably a range of 0.2 mA to 0.3 mA. It is confirmed that the activity dips and the frequency dips do not easily occur even if the oscillation is performed under this condition.

The resonant frequency of the crystal resonator 5 is preferred to coincide with the oscillation frequency of the oscillating unit 1. However, these frequencies need not coincide with each other insofar as the resonant frequency of the crystal resonator 5 is near the oscillation frequency of the oscillating unit 1. The resonant frequency of the crystal resonator 5 is near the oscillation frequency of the oscillating unit 1″ means that at least a part of the frequency signal oscillated by the oscillating unit 1 can pass through the crystal resonator 5 and that the oscillation of the oscillation loop is possible. In this respect, in the case where the resonant frequency of the crystal resonator 5 is within a range of ±10% of the oscillation frequency of the oscillating unit 1, the frequency signal can be obtained by oscillation of the oscillation loop at the oscillation frequency of the oscillating unit 1.

The self-oscillation circuit according to this embodiment provides the following effects. The oscillating unit 1 constituted of the LC oscillation circuit that self-oscillates reduces the drive current for reduction in electric power. Additionally, the activity dips and the frequency dips do not easily occur. In the oscillation loop, the resonator (the crystal resonator 5) with the higher Q-value than that of the oscillating unit 1 is disposed. Accordingly, the entrainment by this resonator improves the overall frequency property of the self-oscillation circuit.

The position where the crystal resonator 5 is disposed in FIG. 1 coincides with the position where the overtone resonator (the crystal resonator) is disposed in the crystal oscillation circuit described in FIG. 3 of Patent Literature 2 in description of the related art. However, the overtone resonator described in Patent Literature 2 is disposed as a waveform-shaping filter that passes overtones of a predetermined order from the frequency signal containing the overtone oscillated by another crystal resonator constituting the oscillator. On the other hand, in the case where the oscillating unit 1 employs the LC oscillation circuit, a frequency signal that has a well-shaped waveform without any overtone is oscillated. Accordingly, it is not necessary to dispose a filter from the view point of waveform shaping. Thus, the crystal resonator 5 of this example is disposed to obtain a unique operation of the entrainment, and has a different function from that of the overtone resonator described in Patent Literature 2.

Here, the resonator disposed in the oscillation loop of the self-oscillation circuit can provide the operation that improves the frequency property by the entrainment at least insofar as the resonator has a higher Q-value than the Q-value of the oscillating unit 1. Practically, for example, disposing a resonator that has a Q-value that is 10 or more times the Q-value of the oscillating unit 1 allows more significantly improving the frequency stability.

In this respect, the crystal resonator 5 with an extremely high Q-value as described above is an appropriate resonator for stabilizing the frequency of this self-oscillation circuit. Here, the crystal resonator 5 applicable to this disclosure is not limited to the AT-cut crystal resonator 5 using thickness-shear vibration illustrated in FIG. 4A and FIG. 4B. The crystal resonator 5 may employ various types of cuts (such as SC-cut and X-cut) and shapes (such as a disk shape and a tuning-fork shape) depending on the oscillation frequency of the oscillating unit 1 or similar parameter. The type of the resonator disposed in the oscillation loop is not limited to the crystal resonator 5 using a crystal, and may be a piezoelectric resonator using another type of piezoelectric material or similar resonator. For example, a ceramic crystal resonator using lead zirconate titanate (PZT) or a dielectric filter that resonates a dielectric resonator by means of electromagnetic field resonance is possible.

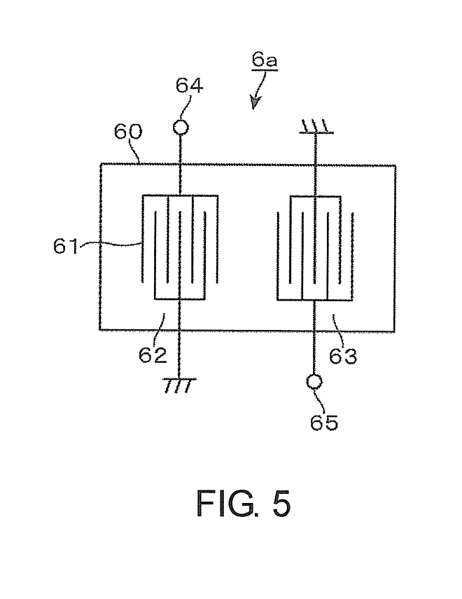

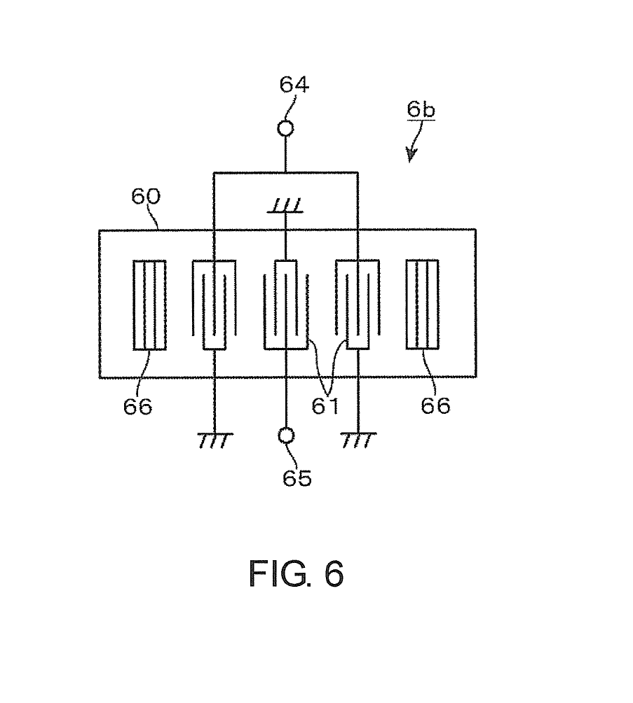

Furthermore, the crystal resonator using these piezoelectric materials is not limited to a crystal resonator using a bulk wave, and may be a crystal resonator using a Surface Acoustic Wave (SAW) as illustrated in FIG. 5 and FIG. 6. In FIG. 5, reference numeral 60 denotes a piezoelectric piece formed of piezoelectric material. At this piezoelectric piece 60, a SAW crystal resonator 6a is disposed. Regarding this SAW crystal resonator 6a, a transmission electrode 62 and a reception electrode 63 that are each constituted of IDT electrodes 61 are arranged in a propagation direction of SAW on the surface of the piezoelectric piece 60. Among frequency signals received at an input port 64, a signal at a resonant frequency determined by the configuration of the IDT electrodes 61 is output from an output port 65 with high power intensity. In FIG. 6, a SAW crystal resonator 6b is a longitudinally-coupled crystal resonator. In the FIG. 6, the portions with the same reference numeral as that in FIG. 5 denotes common components. Reference numeral 66 denotes a grating reflector, and reference numeral 61 denotes an IDT electrode.

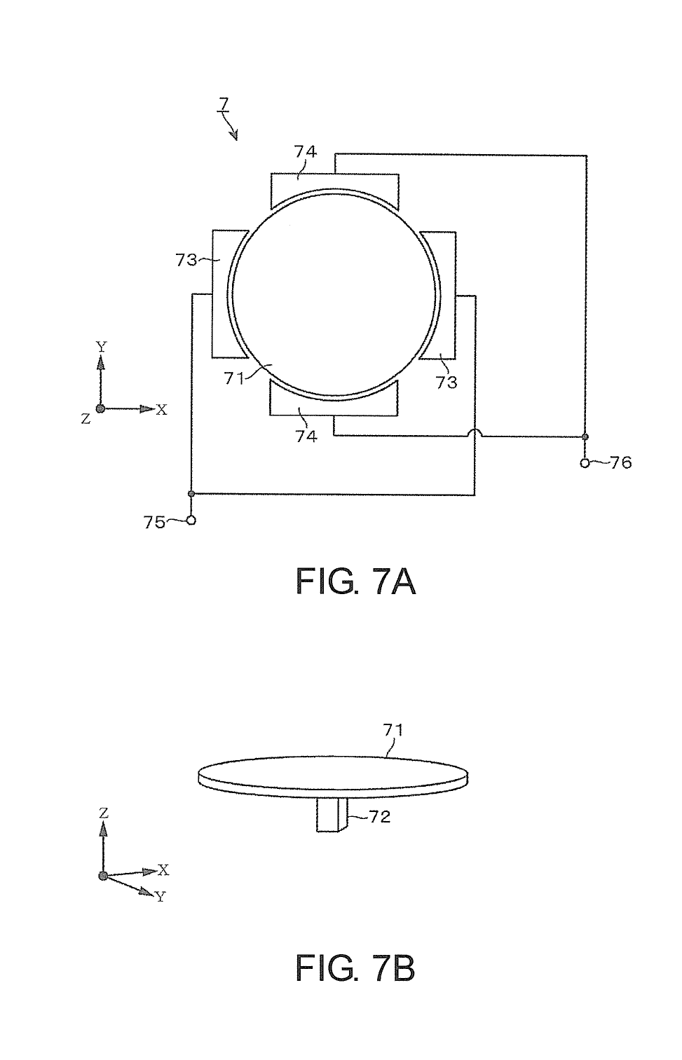

Additionally, the resonator disposed in the oscillation loop of the self-oscillation circuit is not limited to a piezoelectric resonator, and may be a Micro Electro Mechanical Systems (MEMS) crystal resonator that includes a mechanical component part. FIG. 7A and FIG. 7B illustrate a disk crystal resonator 7. A circular plate-shaped disk 71 supported by a support pillar 72 is disposed as a mechanical component part. Four electrodes 73 and 74 are disposed having a gap with this disk 71. The four electrodes 73 and 74 constitute the paired two electrodes 73 and the paired two electrodes 74. These two paired electrodes 73 and 74 (first electrodes 73 and second electrodes 74) are each disposed in a direction intersecting with each other across the disk 71.

In the case where a frequency signal at a predetermined frequency is input between an input port 75 connected to the first paired electrodes 73 and an output port 76 connected to the second paired electrodes 74, the disk 71 provides wine-glass mode vibration corresponding to change in capacitance between the disk 71 and the electrodes 73 and 74 so as to operate as a crystal resonator. In this example, the resonator that can be disposed in the oscillation loop of the self-oscillation circuit is not limited to the example of the disk crystal resonator 7 illustrated in FIG. 7A and FIG. 7B. Apparently, an MEMS crystal resonator that includes a mechanical element part in another shape may be used.

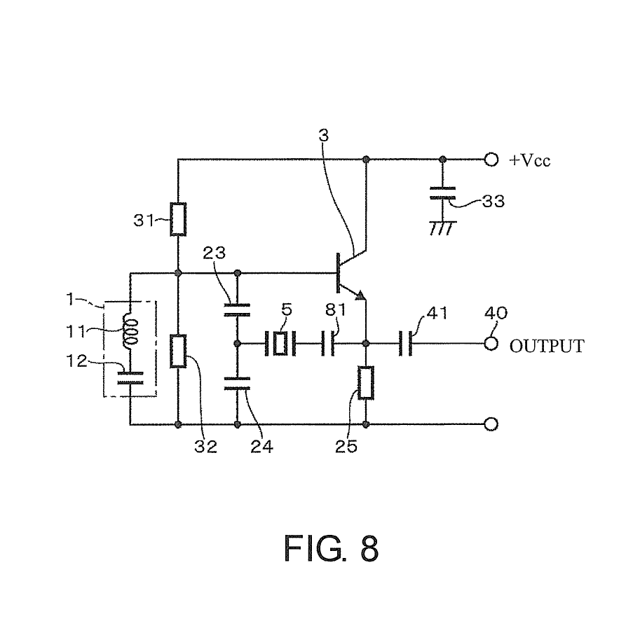

Next, modifications of the self-oscillation circuit will be described. FIG. 8 illustrates an example where a capacitor 81 is connected in series to the latter part of the crystal resonator 5 in order to adjust the resonant frequency. This capacitor 81 may be connected in parallel to the crystal resonator 5. However, the frequency adjustment range is wider in series connection than that in parallel connection.

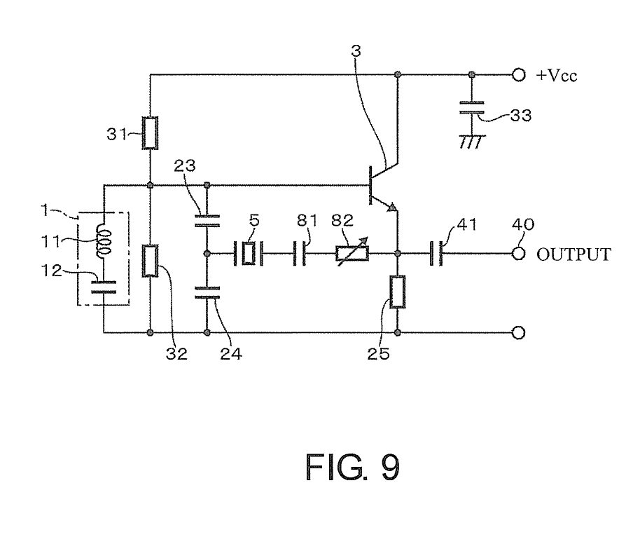

As illustrated in FIG. 9, a variable resistor 82 for controlling the drive current may be disposed at the latter part of the capacitor 81 for frequency adjustment. This capacitor 81 may also be connected in parallel to the crystal resonator 5 (See FIG. 10). In the example of FIG. 10, the variable resistor 82 is connected between the voltage-dividing capacitors 23 and 24 and the crystal resonator 5 to avoid the influence on a feedback resistor 25 disposed at the emitter side of the transistor 3.

As described above, in FIG. 1 and FIG. 8 to FIG. 10, the examples where the crystal resonator 5 is disposed between the voltage-dividing capacitors 23 and 24 and the emitter of the transistor 3 have been described.

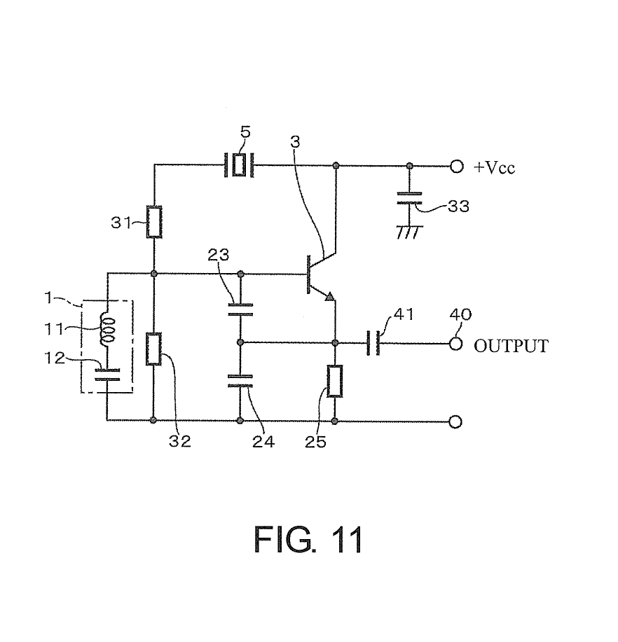

However, the position to dispose the crystal resonator 5 is not limited to this position insofar as the position is in the oscillation loop that includes the oscillating unit 1 and the amplifying unit (the transistor 3). As illustrated in FIG. 11, the crystal resonator 5 may be disposed between the collector of the transistor 3 and the bleeder resistor 31.

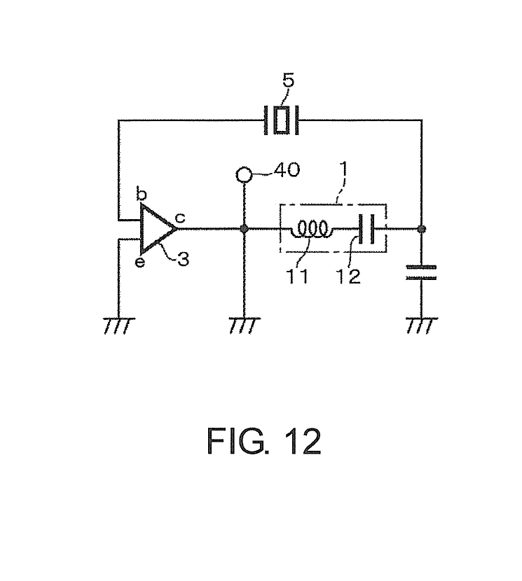

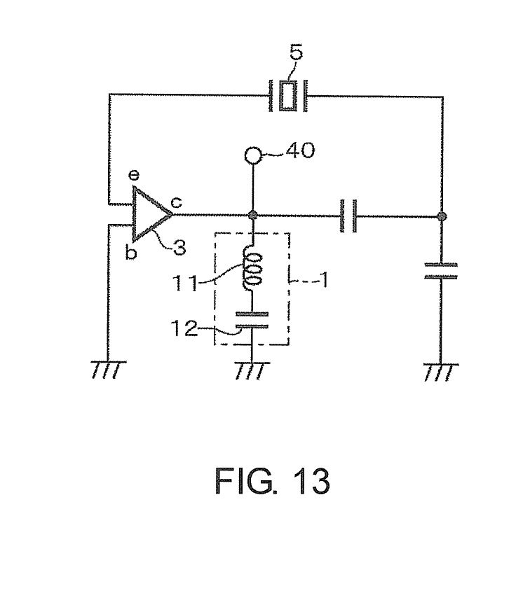

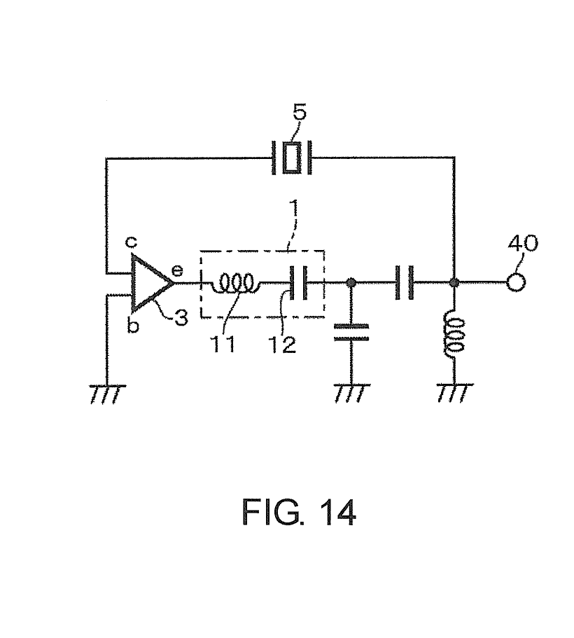

Furthermore, the type of the self-oscillation circuit is not limited to the Colpitts type. A resonator (for example, the crystal resonator 5) may be disposed in an oscillation loop of a Pierce-type self-oscillation circuit illustrated in FIG. 12. Additionally, a resonator may be disposed in an oscillation loop of a Clapp-type self-oscillation circuit illustrated in FIG. 13 or in an oscillation loop of a Butler-type self-oscillation circuit illustrated in FIG. 14. Here, in each diagram of FIG. 12 to FIG. 14, reference numerals “b”, “c”, and “e” with the transistor 3 respectively denotes the base, the collector, and the emitter.

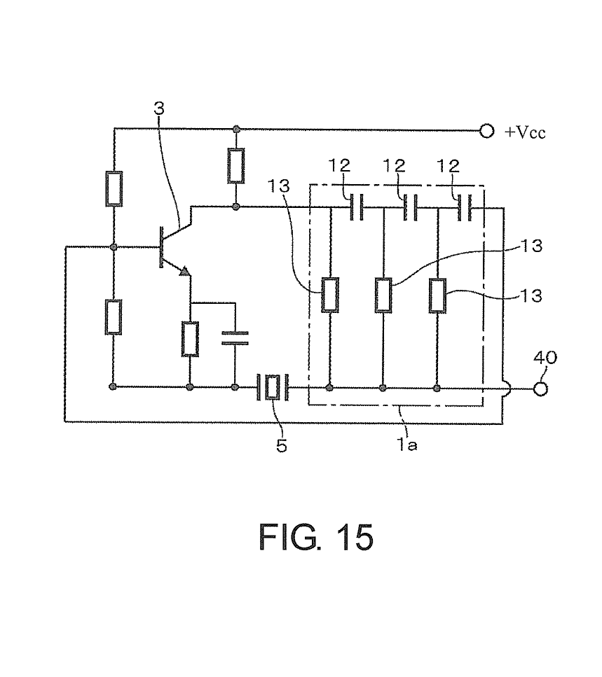

Furthermore, the oscillating unit of the self-oscillation circuit is not limited to the configuration that includes the LC oscillation circuit, and may employ a CR oscillation circuit. In a self-oscillation circuit of FIG. 15, a CR oscillation circuit where circuit sections each constituted of a capacitor 12 (C) and a resistor 13 (R) are connected in three stages is assumed to be an oscillating unit 1a. A resonator (the crystal resonator 5) for entrainment is disposed in an oscillation loop that includes this oscillating unit 1a and an amplifying unit (the transistor 3).

### Working Example

### Experiment

A comparison of temperature characteristics was made between an oscillation frequency of the self-oscillation circuit where the crystal resonator 5 is disposed in the oscillation loop and an oscillation frequency of the conventional crystal oscillation circuit.

### A. Experimental Condition

### Working Example

The self-oscillation circuit in FIG. 1 where the oscillating unit 1 was constituted of the LC oscillation circuit and the crystal resonator 5 was disposed in the oscillation loop was oscillated under the temperature condition of −30° C. to +85° C., so as to measure a frequency versus temperature characteristic. The oscillation frequency of the oscillating unit 1 was 26.0 MHz, the drive current was 0.26 mA, and the crystal resonator 5 employed an AT-cut crystal resonator with a resonant frequency of 26.0 MHz. The load capacitance component at an active circuit side viewed from the crystal resonator 5 (at a circuit side that includes the oscillating unit 1, the bleeder resistors 31 and 32, and the voltage-dividing capacitors 23 and 24) coincided with that of a comparative example. The frequency was measured based on the international standard (IEC 60444-7).

### Comparative Example

In a crystal oscillation circuit, an oscillating unit included an AT-cut crystal resonator of 26.0 MHz instead of the LC oscillation circuit. The crystal oscillation circuit did not have the crystal resonator 5 for entrainment but was otherwise similar to the working example in the circuit configuration. This crystal oscillation circuit was used so as to measure the frequency versus temperature characteristic under the condition similar to that of the working example.

### B. Experimental Result

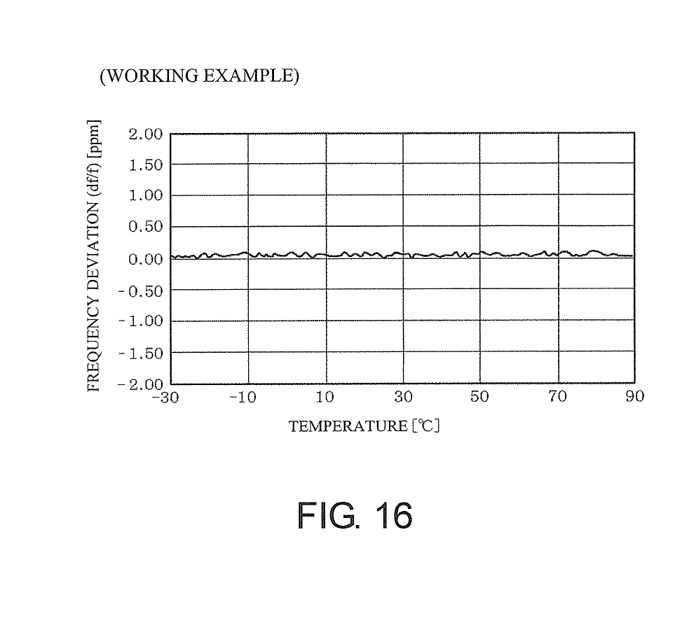

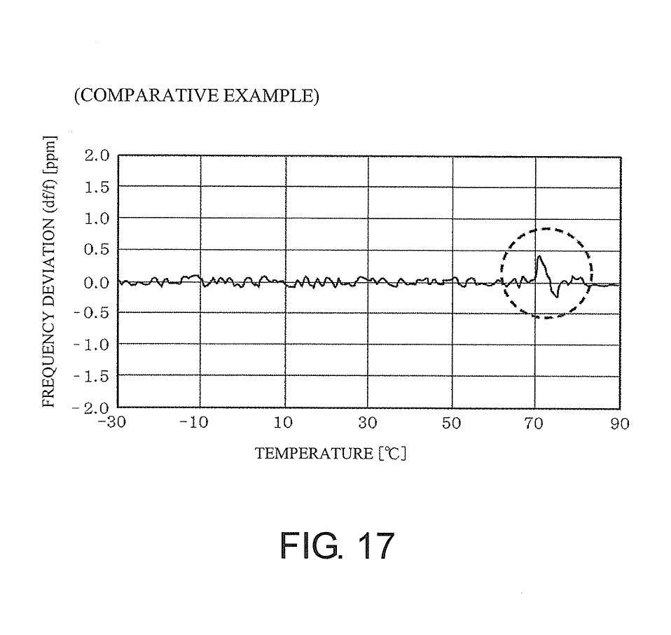

FIG. 16 illustrates the result of the working example while FIG. 17 illustrates the result of the comparative example. In these graphs, the horizontal axis indicates temperature (° C.) and the vertical axis indicates frequency deviation (a ratio df/f of an amount of frequency variation df to an oscillation frequency f) (ppm). In the result of the working example illustrated in FIG. 16, the value of the frequency deviation was within a range of 0 to +0.1 (ppm) over a wide temperature range (−30° C. to +85° C.) at a low drive current of 0.26 mA. This provided a stable frequency versus temperature characteristic.

On the other hand, in the comparative example, a higher drive current of 1.0 mA than that of the working example was needed to stably oscillate this crystal oscillation circuit. Additionally, activity dips and frequency dips where the frequency deviation rapidly varied approximately from +0.5 to −0.2 (ppm) were observed when the temperature condition exceeded +70° C. (illustrated by enclosing with a dashed line in FIG. 17). According to the comparison result between the working example and the comparative example, the self-oscillation circuit where the oscillating unit 1 includes the LC oscillation circuit that self-oscillates and the resonator (the crystal resonator 5) is disposed in the oscillation loop provides a stable frequency versus temperature characteristic under the condition of the low drive current.

The above-described self-oscillation circuit may have the following features.

(a) The Q-value of the resonator is 10 or more times the Q-value of the oscillating unit.
(b) The oscillating unit is one of an LC oscillation circuit and an RC oscillation circuit.
(c) The resonator is one of a piezoelectric resonator and a MEMS crystal resonator. Alternatively, the piezoelectric resonator is a crystal resonator.
(d) The resonator has a resonant frequency in a range of ±10% of the oscillation frequency of the oscillating unit.
(e) A drive current for oscillating the oscillating unit is equal to or less than 0.3 mA.

With this disclosure, the oscillating unit that performs self-oscillation can oscillate at a comparatively small drive current. This ensures reduction in electric power. Additionally, activity dips and frequency dips do not easily occur. The resonator that has a higher Q-value compared with the oscillating unit is disposed in the oscillation loop. Accordingly, the entrainment by this resonator improves the overall frequency property of the self-oscillation circuit.

The principles, preferred embodiment and mode of operation of the present disclosure have been described in the foregoing specification. However, the disclosure which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present disclosure. Accordingly, it is expressly intended that all such variations, changes and equivalents which fall within the spirit and scope of the present disclosure as defined in the claims, be embraced thereby.

What is claimed is:

1. A self-oscillation circuit, comprising:
an oscillating unit, configured to self-oscillate;
an amplifying unit, configured to amplify a frequency signal oscillated at the oscillating unit and to feed back the amplified frequency signal to the oscillating unit; and
a resonator, disposed in an oscillation loop that includes the oscillating unit and the amplifying unit, wherein
the resonator has a resonant frequency near an oscillation frequency of the oscillating unit and has a higher Q-value than a Q-value of the oscillating unit.

2. The self-oscillation circuit according to claim 1, wherein
the resonant frequency allows at least a part of the frequency signal oscillated by the oscillating unit to pass through the resonator and allows the oscillation of the oscillation loop.

3. The self-oscillation circuit according to claim 1, wherein
the resonant frequency is in a range of ±10% of the oscillation frequency of the oscillating unit.

4. The self-oscillation circuit according to claim 1, wherein
the Q-value of the resonator is 10 or more times the Q-value of the oscillating unit.

5. The self-oscillation circuit according to claim 1, wherein
the oscillating unit is one of an LC oscillation circuit and an RC oscillation circuit.

6. The self-oscillation circuit according to claim 4, wherein
the oscillating unit is one of an LC oscillation circuit and an RC oscillation circuit.

7. The self-oscillation circuit according to claim 1, wherein
the resonator is one of a piezoelectric resonator and an MEMS crystal resonator.

8. The self-oscillation circuit according to claim 4, wherein
the resonator is one of a piezoelectric resonator and an MEMS crystal resonator.

9. The self-oscillation circuit according to claim 5, wherein
the resonator is one of a piezoelectric resonator and an MEMS crystal resonator.

10. The self-oscillation circuit according to claim 7, wherein
the piezoelectric resonator is a crystal resonator.

11. The self-oscillation circuit according to claim 8, wherein
the piezoelectric resonator is a crystal resonator.

12. The self-oscillation circuit according to claim 9, wherein
the piezoelectric resonator is a crystal resonator.

13. The self-oscillation circuit according to claim 1, wherein
a drive current for oscillating the oscillating unit is equal to or less than 0.3 mA.

14. The self-oscillation circuit according to claim 4, wherein
a drive current for oscillating the oscillating unit is equal to or less than 0.3 mA.

15. The self-oscillation circuit according to claim 5, wherein
a drive current for oscillating the oscillating unit is equal to or less than 0.3 mA.

16. The self-oscillation circuit according to claim 7, wherein
a drive current for oscillating the oscillating unit is equal to or less than 0.3 mA.

17. The self-oscillation circuit according to claim 10, wherein
a drive current for oscillating the oscillating unit is equal to or less than 0.3 mA.
